(19) United States
(12) Patent Application Publication
(10) Pub. No.: US 2009/0047608 A1
(43) Pub. Date: Feb. 19, 2009

(54) APPARATUS AND METHOD FOR TRANSFERRING FEATURES TO AN EDGE OF A WAFER

(76) Inventors: W. Thomas Novak, Hillsborough, CA (US); Daniel Gene Smith, Oro Valley, AZ (US)

Correspondence Address: Roeder & Broder LLP, 5560 Chelsea Avenue, La Jolla, CA, 92037, US

(21) Appl. No.: 12/191,108

(22) Filed: Aug. 13, 2008

Related U.S. Application Data
(60) Provisional application No. 60/964,501, filed on Aug. 13, 2007.

(51) Int. Cl. G03F 7/20; G03B 27/42

(52) U.S. Cl. 430/322; 355/53

(57) ABSTRACT

An edge shot (“ES”) exposure apparatus (14) for transferring edge features (ef) to a substrate edge region (222) of a substrate (18) includes a feature transferer (55), and an ES wafer stage assembly (62). The feature transferer (55) transfers one or more edge features (ef) to the substrate edge region (222), while the ES wafer stage assembly (62) rotates the substrate (18) about a substrate axis (23). This allows the feature transferer (55) to transfer the edge features (ef) to a plurality of alternative locations in the substrate edge region (222). The ES exposure apparatus (14) can be used in conjunction with a primary exposure apparatus (12) that transfers usable features (uf) to a substrate usable region (220) of the substrate (18). With this design, the primary exposure apparatus (12) can be transferring usable features (uf) to a first substrate (18A) while the ES exposure apparatus (14) is transferring edge features (ef) to a second substrate (18B). As a result thereof, the overall throughput is improved because the primary exposure apparatus (12) does not need to transfer features to the substrate edge region (222).

### RELATED INVENTIONS

This application claims priority on U.S. Provisional Application Ser. No. 60/964,501, filed Aug. 13, 2007 and entitled “System for Edge-Shot Exposure”. As far as permitted, the contents of U.S. Provisional Application Ser. No. 60/964,501 are incorporated herein by reference.

### BACKGROUND

Exposure apparatuses for semiconductor processing are commonly used to transfer features from a reticle onto a disk shaped semiconductor wafer during semiconductor processing. A typical exposure apparatus includes an illumination source, a reticle stage assembly that positions a reticle, an optical assembly, a wafer stage assembly that positions a semiconductor wafer, a measurement system, and a control system.

Typically, the disk shaped wafer is divided into a plurality of rectangular shaped integrated circuits and the edges of the wafer around the rectangular integrated circuits are not used. With this design, the integrated circuits define a substrate usable region of the wafer, and the rest of the wafer defines a substrate edge region that is not used.

Frequently, for high performance circuit production, the exposure apparatus transfers features to both the substrate usable region and the substrate edge region even though the substrate edge region is not used for functional circuits. Unfortunately, this reduces the throughput of the exposure apparatus.

Alternatively, to increase throughput of the exposure apparatus, features are transferred by the exposure apparatus only to the substrate usable region and not to the substrate edge region. However, as a result thereof, the characteristics of the substrate edge region will be different than the characteristics of the substrate usable region. This can adversely influence a subsequent Chemical-Mechanical Process that is performed on the wafer. More specifically, the different characteristics between the substrate edge region and the substrate usable region can cause the over-polishing or under-polishing of the substrate usable region adjacent to the substrate edge region. This can reduce the quality of the circuits near the substrate edge region.

Moreover, etching uniformity, and the outgassing of semiconductor process materials that are deposited into the circuit features can also be influenced by not transferring features to the substrate edge region. This can also reduce the quality of the circuits near the substrate edge region.

### SUMMARY

The present invention is directed to an edge shot (“ES”) exposure apparatus that is used for transferring edge features to a substrate edge region of a substrate. In one embodiment, the ES exposure apparatus includes a feature transferee, and an ES wafer stage assembly. The feature transferer transfers one or more edge features to the substrate edge region, while the stage assembly rotates the substrate about a substrate axis or rotates the feature transferee. This allows the feature transferer to transfer edge features to a plurality of alternative locations in the substrate edge region. Further, as provided herein, the ES exposure apparatus can be used in conjunction with a primary exposure apparatus that transfers usable features to a substrate usable region of the substrate.

With the designs provided herein, the primary exposure apparatus can be transferring usable features to a first substrate while the ES exposure apparatus is transferring edge features to a second substrate. Further, features are transferred to the entire wafer, and the primary exposure apparatus is not required to transfer features to the substrate edge region. Thus, the quality of the wafer is maintained, while only using the primary exposure apparatus to transfer features to the substrate usable region. As a result thereof, the overall throughput is improved because the primary exposure apparatus does not need to transfer features to the substrate edge region.

Further, with this design, features are ultimately transferred to both the substrate usable region and the substrate edge region. As a result thereof, the characteristics of the substrate edge region can be similar to the characteristics of the substrate usable region. This allows for a more uniform, Chemical-Mechanical Process to be performed on the wafer and higher quality circuits. Further, the uniformity of the polishing and other characteristics on the wafer can promote more uniformity in subsequent processes, such as etching, that are performed on the wafer.

In one embodiment, the feature transferer includes an ES reticle having a pattern with one or more features, and an ES illumination system that directs an illumination beam at the ES reticle to create an image beam that is directed at the substrate. Further, the feature transferer can include a shutter that is movable relative to the reticle to quickly adjust the shape of the image beam that is directed at the substrate. With this design, the image beam can be quickly adjusted to follow the contours of the substrate usable region.

In certain designs, the ES reticle includes a plurality of alternative patterns, and the feature transferer includes an ES reticle stage assembly that moves the desired pattern into the path of the illumination beam. The ES illumination system can include a pulsing laser or a continuous output laser.

Additionally, the ES exposure apparatus can include a mask positioned between the reticle and the substrate that inhibits stray light from image beam from being directed at a substrate usable region of the substrate.

Moreover, the present invention is directed to a method for manufacturing a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an exposure assembly having features of the present invention;

FIG. 2 is a simplified top view of one non-exclusive embodiment of a substrate that was processed with the exposure assembly of FIG. 1;

FIG. 3A is a simplified top illustration of a first embodiment of an ES reticle having features of the present invention;

FIG. 3B is a simplified top illustration of a second embodiment of an ES reticle having features of the present invention;

FIG. 3C is a simplified top illustration of a third embodiment of an ES reticle having features of the present invention;

FIG. 4A is a simplified top view of a portion of an image beam, a shutter assembly, and a portion of the substrate with the shutter assembly in a first shutter position;

FIG. 4B is a simplified side view of the image beam, a shutter, and a portion of the substrate with the shutter in the first shutter position;

FIG. 5A is a simplified top view of a portion of an image beam, the shutter assembly, and a portion of the substrate with the shutter assembly in a second shutter position;

FIG. 5B is a simplified side view of the image beam, the shutter, and a portion of the substrate with the shutter in the second shutter position;

FIG. 6A is a simplified top view of one non-exclusive embodiment of a portion of the substrate with a plurality of edge features transferred thereto;

FIG. 6B is view of another portion of a substrate;

FIGS. 6C-6E illustrate portions of alternative edge shots transferred to a wafer;

FIG. 7A is a simplified top illustration and FIG. 7B is a simplified cut-away illustration of a portion of another embodiment of an edge shot exposure apparatus having features of the present invention;

FIGS. 8A and 8B are a simplified illustrations of a portion of yet another embodiment of an edge shot exposure apparatus having features of the present invention;

FIG. 9A is a simplified illustration of another embodiment of an ES exposure apparatus having features of the present invention;

FIG. 9B is a simplified illustration of yet another embodiment of an ES exposure apparatus having features of the present invention;

FIGS. 10A and 10B illustrate alternative embodiments of an ES reticle having features of the present invention;

FIG. 11A is a flow chart that outlines a process for manufacturing a device in accordance with the present invention; and

FIG. 11B is a flow chart that outlines device processing in more detail.

### DESCRIPTION

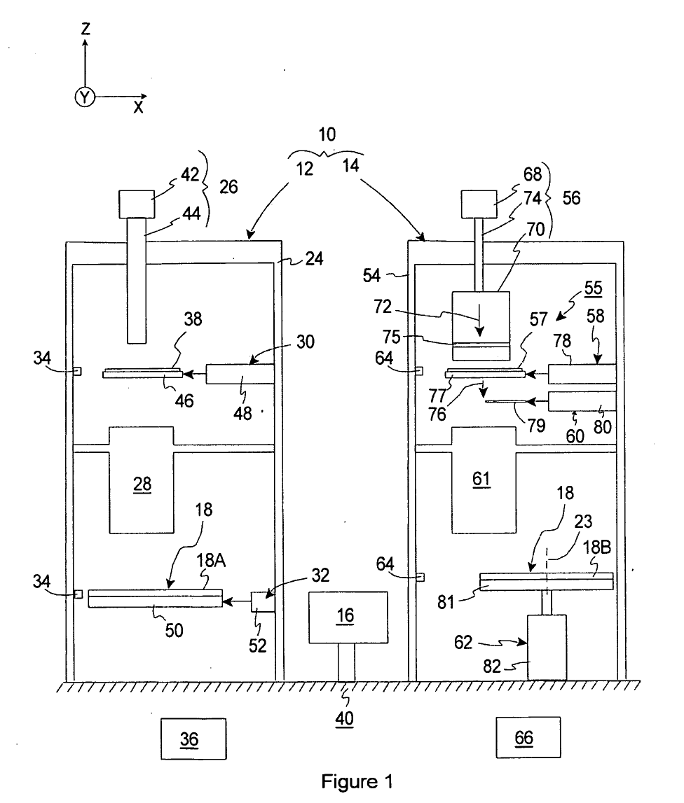

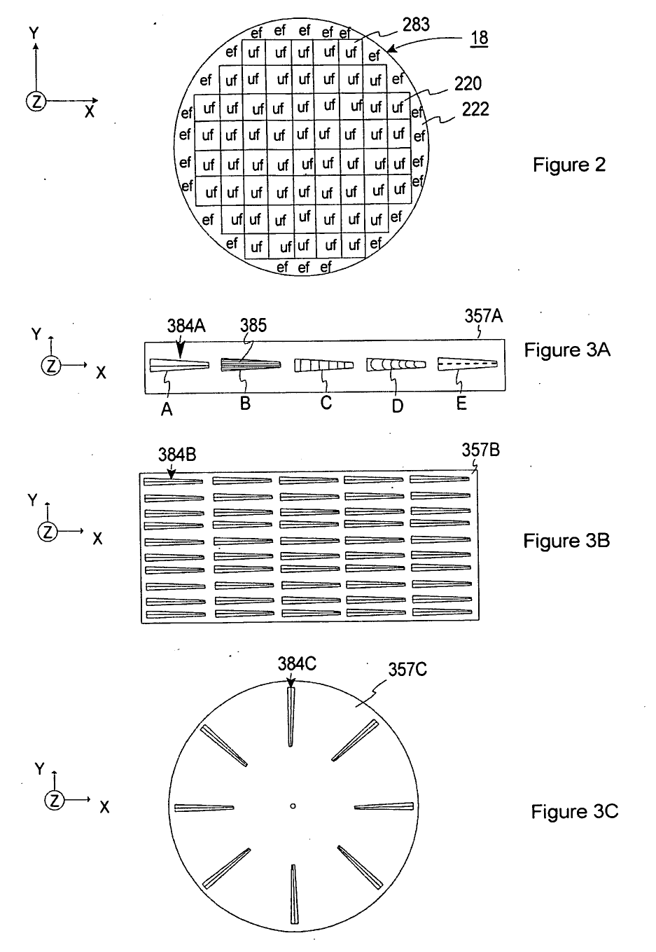

FIG. 1 is a schematic illustration of a precision assembly, namely an exposure assembly 10 that includes a primary exposure apparatus 12, an edge shot (“ES”) exposure apparatus 14, and a transfer mechanism 16 (illustrated as a box) that can be used to process a substrate 18 such as a semiconductor wafer. As an overview, in certain embodiments, (i) the primary exposure apparatus 12 is used for transferring usable features “uf” (illustrated in FIG. 2) to only a substrate usable region 220 (illustrated in FIG. 2) of the substrate 18, (ii) the ES exposure apparatus 14 is used for rapidly transferring edge features “ef” (illustrated in FIG. 2) to only a substrate edge region 222 (illustrate in FIG. 2) of the substrate 18, and (iii) the transfer mechanism 16 is used for transferring the substrate 18 between the exposure apparatuses 12, 14.

It should be noted that one or more of the components illustrated in FIG. 1 can be optional. For example, the transfer mechanism 16 can be optional if the ES exposure apparatus 14 is integrated into the primary exposure apparatus 12.

With the designs provided herein, the primary exposure apparatus 12 can be transferring usable features to a first substrate 18A while the ES exposure apparatus 14 is transferring edge features to a second substrate 18B. Further, the features are transferred to the entire wafer 18, and the primary exposure apparatus 12 is not required to transfer features to the substrate edge region 222. Thus, the quality of the wafer 18 is maintained, while using the primary exposure apparatus 12 to transfer features only to the substrate usable region 220. As a result thereof, the overall throughput of the precision assembly 10 is improved because the primary exposure apparatus 12 does not need to transfer features to the substrate edge region 222.

It should be noted that the edge features are not used in integrated circuits. As a result thereof, the precision required to transfer the edge features is less than the precision required to transfer the usable features. Thus, the ES exposure apparatus 14 does not have to be as accurate as the primary exposure apparatus 12, and the ES exposure apparatus 14 can be less expensive to manufacture and operate.

It should also be noted that, the primary exposure apparatus 12 can transfer the usable features to the substrate usable region 220 prior or after the ES exposure apparatus 14 transfers the edge features to the substrate edge region 222. Stated in another fashion, the transfer mechanism 16 can (i) first transfer the substrate 18 to the primary exposure apparatus 14 for processing the substrate usable region 220 and subsequently to the ES exposure apparatus 16 for processing of the substrate edge region 222, or (ii) first transfer the substrate 18 to the ES exposure apparatus 16 for processing the substrate edge region 222 and subsequently to the primary exposure apparatus 14 for processing of the substrate usable region 220. A determination of which process is performed first can depend upon the type of photo resist used in the substrate 18 and/or other factors.

Further, it should be noted that either of the exposure apparatuses 12, 14 can be referred to as a first or second exposure apparatus.

Additionally, it should be noted that a number of Figures include an orientation system that illustrates an X axis, a Y axis that is orthogonal to the X axis and a Z axis that is orthogonal to the X and Y axes. Further, any of these axes can also be referred to as the first, second, and/or third axes.

The exposure assembly 10 discussed herein is particularly useful as a photolithography system for semiconductor manufacturing. However, the exposure assembly 10 provided herein is not limited to a photolithography system for semiconductor manufacturing. The exposure assembly 10, for example, can be used as an LCD photolithography system that exposes a liquid crystal display device pattern onto a rectangular glass plate or a photolithography system for manufacturing a thin film magnetic head.

The design of the primary exposure apparatus 12 can be varied to achieve the desired throughput, and quality and density of usable features on the substrate 18. In FIG. 1, the primary exposure apparatus 12 includes a primary apparatus frame 24, a primary illumination system 26 (irradiation apparatus), a primary optical assembly 28, a primary reticle stage assembly 30, a primary wafer stage assembly 32, a primary measurement system 34, and a primary control system 36.

The primary exposure apparatus 12 transfers a pattern (not shown) of an integrated circuit from a primary reticle 38 onto the substrate usable region 220 of the substrate 18. The primary exposure apparatus 12 mounts to a mounting base 40, e.g., the ground, a base, or floor or some other supporting structure.

There are a number of different types of lithographic devices. For example, the primary exposure apparatus 12 can be used as a scanning type photolithography system that exposes the pattern from the reticle 38 onto the wafer 18 with the reticle 38 and the wafer 18 moving synchronously. In a scanning type lithographic device, the reticle 38 is moved perpendicularly to an optical axis of the primary optical assembly 28 by the primary reticle stage assembly 30 and the wafer 18 is moved perpendicularly to the optical axis of the primary optical assembly 28 by the primary wafer stage assembly 32. Scanning of the reticle 38 and the wafer 18 occurs while the reticle 38 and the wafer 18 are moving synchronously.

Alternatively, the primary exposure apparatus 12 can be a step-and-repeat type photolithography system that exposes the reticle 38 while the reticle 38 and the wafer 18 are stationary. In the step and repeat process, the wafer 18 is in a constant position relative to the reticle 38 and the primary optical assembly 28 during the exposure of an individual field. Subsequently, between consecutive exposure steps, the wafer 18 is consecutively moved with the primary wafer stage assembly 32 perpendicularly to the optical axis of the primary optical assembly 28 so that the next field of the wafer 18 is brought into position relative to the primary optical assembly 28 and the reticle 38 for exposure. Following this process, the images on the reticle 38 are sequentially exposed onto the fields of the wafer 18, and then the next field of the wafer 18 is brought into position relative to the primary optical assembly 28 and the reticle 38.

The primary apparatus frame 24 is rigid and supports the components of the primary exposure apparatus 12. The primary apparatus frame 24 illustrated in FIG. 1 supports the primary reticle stage assembly 30, the primary optical assembly 28, the primary illumination system 26, and the primary wafer stage assembly 32 above the mounting base 40.

The primary illumination system 26 includes a primary illumination source 42 and a primary illumination optical assembly 44. The primary illumination source 42 emits a beam (irradiation) of light energy. The primary illumination optical assembly 44 guides the beam of light energy from the primary illumination source 42 to the primary reticle 38. The beam illuminates selectively different portions of the primary reticle 38 and exposes the wafer 18. In FIG. 1, the primary illumination source 42 is illustrated as being supported above the primary reticle stage assembly 30. Typically, however, the primary illumination source 42 is secured to one of the sides of the primary apparatus frame 24 and the energy beam from the primary illumination source 42 is directed to above the primary reticle stage assembly 30 with the primary illumination optical assembly 44.

The primary illumination source 42 can be a g-line source (436 nm), an i-line source (365 nm), a KrF excimer laser (248 nm), an ArF excimer laser (193 nm) or an F₂ laser (157 nm). Alternatively, the primary illumination source 42 can generate charged particle beams such as an x-ray or an electron beam. For instance, in the case where an electron beam is used, thermionic emission type lanthanum hexaboride (LaB₆) or tantalum (Ta) can be used as a cathode for an electron gun. Furthermore, in the case where an electron beam is used, the structure could be such that either a mask is used or a pattern can be directly formed on a substrate without the use of a mask.

The primary optical assembly 28 projects and/or focuses the light from the primary reticle 38 to the wafer 18. Depending upon the design of the primary exposure apparatus 12, the primary optical assembly 28 can magnify or reduce the image illuminated on the primary reticle 38.

When far ultra-violet rays such as the excimer laser is used, glass materials such as quartz and fluorite that transmit far ultra-violet rays can be used in the optical assembly 28. When the F₂ type laser or x-ray is used, the optical assembly 28 can be either catadioptric or refractive (a reticle should also preferably be a reflective type), and when an electron beam is used, electron optics can consist of electron lenses and deflectors. The optical path for the electron beams should be in a vacuum.

Also, with an exposure device that employs vacuum ultra-violet radiation (VUV) of wavelength 200 nm or lower, use of the catadioptric type optical system can be considered.

The primary reticle stage assembly 30 holds and positions the primary reticle 38 relative to the primary optical assembly 28 and the wafer 18. The primary reticle stage assembly 30 can include a primary reticle stage 46, and a primary reticle stage mover 48. The size, shape, and design of each these components can be varied. The primary reticle stage 46 retains the primary reticle 38. In one embodiment, the primary reticle stage 46 can include a chuck (not shown) for holding the primary reticle 46.

The primary reticle stage mover 48 moves and positions the primary reticle stage 46. For example, the primary reticle stage mover 48 can move the primary reticle stage 46 and the primary reticle 38 along the Y axis, along the X axis, and about the Z axis. Alternatively, for example, the primary reticle stage mover 48 could be designed to move the primary reticle stage 46 and the primary reticle 38 with more than three degrees of freedom, or less than three degrees of freedom. For example, the primary reticle stage mover 48 can include one or more linear motors, rotary motors, planar motors, voice coil actuators, or other type of actuators.

Somewhat similarly, the primary wafer stage assembly 32 holds and positions the wafer 18 with respect to the projected image of the illuminated portions of the primary reticle 38. The primary wafer stage assembly 32 can include a primary wafer stage 50, and a primary wafer stage mover 52. The size, shape, and design of each these components can be varied. The primary wafer stage 50 retains the wafer 18. In one embodiment, the primary wafer stage 50 can include a chuck (not shown) for holding the wafer 18.

The primary wafer stage mover 52 moves and positions the primary wafer stage 50. For example, the primary wafer stage mover 52 can move the primary wafer stage 50 and the wafer 18 along the Y axis, along the X axis, and about the Z axis. Alternatively, for example, the primary wafer stage mover 52 could be designed to move the primary wafer stage 50 and the wafer 18 with more than three degrees of freedom, or less than three degrees of freedom. For example, the primary wafer stage mover 52 can include one or more linear motors, rotary motors, planar motors, voice coil actuators, or other type of actuators.

The primary measurement system 34 monitors movement of the primary reticle 38 and the wafer 18 relative to the primary optical assembly 28 or some other reference. With this information, the primary control system 36 can control the primary reticle stage assembly 30 to precisely position the primary reticle 38 and the primary wafer stage assembly 32 to precisely position the wafer 18. For example, the primary measurement system 34 can utilize multiple laser interferometers, encoders, and/or other measuring devices.

The primary control system 36 is connected to the primary reticle stage assembly 30, the primary wafer stage assembly 32, and the primary measurement system 34. The primary control system 36 receives information from the primary measurement system 34 and controls the stage assemblies 30, 32 to precisely position the primary reticle 38 and the primary wafer 18. The primary control system 36 can include one or more processors and circuits.

The design of the ES exposure apparatus 14 can be varied to achieve the desired throughput, and quality and density of edge features on the substrate edge region 222. In FIG. 1, the ES exposure apparatus 14 includes (i) an ES apparatus frame 54, (ii) a feature transferer 55 that includes an ES illumination system 56 (irradiation apparatus), an ES reticle 57, an ES reticle stage assembly 58, and a shutter assembly 60, (iii) an ES optical assembly 61, (iv) an ES wafer stage assembly 62, (v) an ES measurement system 64, and (vi) an ES control system 66. The ES exposure apparatus 14 is particularly useful as a lithographic device that transfers edge features from the ES reticle 57 onto the substrate edge region 222. In FIG. 1, the ES exposure apparatus 14 mounts to the mounting base 40.

In one non-exclusive embodiment, the ES exposure apparatus 14 transfers the edge features from the ES reticle 57 onto the wafer 18 with the ES reticle 57 stationary and the wafer 18 rotating at a constant speed about a substrate axis 23 (about the Z axis). Following this process, the edge features on the ES reticle 57 are rapidly and sequentially exposed onto the substrate edge region 222 of the wafer 18. Alternatively, for example, the edge features can be transferred to the wafer 18 while that wafer 18 is being rotated about the substrate axis 23 at a non-constant speed and/or step like fashion. For example, the wafer 18 can be rotated at a slower rate in certain areas to the wafer 18 to transfer more edge features to that area of the wafer 18.

The ES primary apparatus frame 54 is rigid and supports the components of the ES exposure apparatus 14. The ES apparatus frame 54 illustrated in FIG. 1 supports the ES reticle stage assembly 58, the ES optical assembly 61, the ES illumination system 56, and the ES wafer stage assembly 52 above the mounting base 40.

The ES illumination system 56 includes an ES illumination source 68 and an ES illumination optical assembly 70. The ES illumination source 68 emits an illumination beam 72 (illustrated as an arrow). The ES illumination optical assembly 70 guides the illumination beam 72 from the ES illumination source 68 to the ES reticle 57. The illumination beam 72 illuminates selectively different portions of the ES reticle 57 and exposes the wafer 18. In FIG. 1, the ES illumination source 68 is illustrated as being supported above the ES reticle stage assembly 58. However, the ES illumination source 68 is secured to one of the sides of the ES apparatus frame 54 and the illumination beam 72 from the ES illumination source 68 is directed to above the ES reticle stage assembly 58 with the ES illumination optical assembly 70.

In one, non-exclusive embodiment, the ES illumination source 68 can be a 193 nm laser source having a pulse rate 1 kHz. Alternatively, the laser source can generate a wavelength that is greater than or less 193 nm, and/or have a pulse rate that is greater than or less than 1 kHz. With this design, the system can expose relatively small radial segments of the wafer edge in a step wise fashion.

In another embodiment, the laser source is a continuous output laser. With this design, the system can expose relatively small radial segments of the wafer edge in a continuous fashion.

In principle, any light source generating sufficient intensity light with a wavelength that is appropriate for the sensitivity of the photo resist of wafer can be utilized. However, the wavelength of the laser source utilized is somewhat dependent on the resolution of the edge features being transferred to the wafer 18.

Further, in one embodiment, the ES illumination optical assembly 70 includes a fiber optic cable 74 and one or more lenses 75 (only one is shown in phantom) that projects and/or focuses the illumination beam 72.

The ES reticle 57 includes one or more reticle patterns (not shown in FIG. 1). For example, as described in more detail below, the reticle patterns can be aligned in a one dimensional array, a two dimensional array, or around a circumference of a disk shaped reticle. In FIG. 1, the ES reticle 57 is a transmissive type reticle in which the illumination beam 72 is directed at and a portion transmitted through the ES reticle 57. It should be noted that the portion of the illumination beam 72 that is transmitted through the ES reticle 57 shall be referred to herein as an image beam 76 (represented as an arrow). It should be noted that the image beam 76 is also sometimes referred to herein as an edge shot. Non-exclusive examples of suitable ES reticles 57 are illustrated in FIGS. 3A-3C and discussed below.

Alternatively, for example, the ES reticle 57 can be a reflective type reticle where the illumination beam 72 is directed at and reflected off of the ES reticle 57.

The ES reticle stage assembly 58 holds and positions the ES reticle 57 relative to the ES optical assembly 61 and the wafer 18. The ES reticle stage assembly 58 can include an ES reticle stage 77, and an ES reticle stage mover 78. The size, shape, and design of each these components can be varied. The ES reticle stage 77 retains the ES reticle 57 and can include a chuck (not shown) for holding the ES reticle 57. It should be noted that in certain designs, the ES reticle stage 77 can be optional, and that the ES reticle 57 can be directly attached to the ES reticle stage mover 78.

The ES reticle stage mover 78 moves and positions the ES reticle stage 77. For example, if the reticle patterns on the ES reticle 57 are aligned in a one dimensional array, the ES reticle stage mover 78 can be designed to move the ES reticle 57 along one axis. Alternatively, if the reticle patterns on the ES reticle 57 are aligned in a two dimensional array, the ES reticle stage mover 78 can be designed to move the ES reticle 57 along two axes. Still alternatively, if the reticle patterns on the ES reticle 57 are aligned around a circumference of a disk, the ES reticle stage mover 78 can be designed to rotate the ES reticle 57 around the Z axis. For example, the ES reticle stage mover 78 can include one or more linear motors, rotary motors, planar motors, voice coil actuators, or other type of actuators.

The shutter assembly 60 can be used to selectively block a portion or all of the image beam 76. As a result thereof, the shutter assembly 60 can be used to selectively change the shape of the image beam 76 that is directed onto the wafer 18 and inhibit the image beam 76 from being directed onto the substrate usable region 220. For example, the shutter assembly 60 can be used to precisely adjust a radial length of the image beam 76 and a radial length of the edge features that are being transferred to the wafer 18. In one embodiment, the shutter assembly 60 includes a shutter 79 that blocks light, and a shutter mover 80 that selectively moves the shutter 79. The shutter assembly 60 is described in more detail below.

It should be noted that in certain embodiments, the ES reticle 57 and the shutter 79 should be in close proximity to each other along the Z axis.

The ES optical assembly 61 projects and/or focuses the image beam 76 onto the wafer 18. Depending upon the design of the ES exposure apparatus 14, the ES optical assembly 61 can magnify or reduce the image beam 76.

The ES wafer stage assembly 62 holds and positions the wafer 18 with respect to the image beam 76. The ES wafer stage assembly 62 can include an ES wafer stage 81, and an ES wafer stage mover 82. The size, shape, and design of each these components can be varied. The ES wafer stage 81 retains the wafer 18 and can include a chuck (not shown) for holding the wafer 18.

The ES wafer stage mover 82 moves and positions the ES wafer stage 81. For example, the ES wafer stage mover 82 can rotate the ES wafer stage 81 and the wafer 18 about the Z axis (i.e. the substrate axis 23). Alternatively, the ES wafer stage mover 82 could be designed to move the ES wafer stage 80 and the wafer 18 with more than one degree of freedom. For example, the ES wafer stage mover 82 could be designed to also include an X-Y stage (not shown) that moves the wafer 18 along the X axis and along the Y axis, in addition to rotation about the Z axis. As a non-exclusive example, the ES wafer stage mover 82 can include a rotary motor, or another type of actuator.

In one non-exclusive embodiment, the wafer stage mover 82 is designed to rotate the wafer 18 at approximately six rotations a minute (36 degrees per seconds). With this design, the wafer stage mover 82 can rotate the wafer 18 three hundred and sixty degrees in approximately ten seconds and the edge features can be transferred to the wafer 18 in approximately ten seconds. With this design, the ES exposure apparatus 14 can transfer the edge features to the second wafer 18B within the same time frame that the primary exposure apparatus 12 transfers the usable features to the first wafer 18A. As a result thereof, the primary exposure apparatus 12 is not waiting idle while the edge features are being transferred by the ES exposure apparatus 14.

In this embodiment, the wafer stage mover 82 is designed to rotate the wafer approximately 360 degrees. Further, the wafer stage mover 82 could be designed to rotate the wafer multiple times during the transfer of features to the substrate edge region.

The ES measurement system 64 monitors movement of the ES reticle 57 and the wafer 18 relative to the ES optical assembly 61 or some other reference. With this information, the ES control system 66 can control the ES reticle stage assembly 58 to precisely position the ES reticle 57, the shutter mover 80 to precisely position the shutter 79, and the ES wafer stage assembly 62 to precisely position the wafer 18. For example, the ES measurement system 64 can utilize multiple laser interferometers, encoders, and/or other measuring devices.

Because, the edge features are not used in integrated circuits, the precision required to transfer the edge features is not as much as the precision required to transfer the usable features. Thus, the ES measurement system 64 does not have to be as accurate as the primary measurement system 34 described above.

The ES control system 66 is connected to the ES illumination source 68, the ES reticle stage assembly 58, the shutter mover 80, the ES wafer stage assembly 62, and the primary measurement system 34. The ES control system 66 receives information from the ES measurement system 64 and controls the movers 78, 80, 82 to precisely position the ES reticle 57, the shutter 79, and the wafer 18. The ES control system 66 can include one or more processors and circuits.

It should be noted that primary control system 36 and the ES control system 66 can be integrated into a single control system that controls both exposure apparatuses 12, 14.

In certain embodiments, the ES exposure apparatus 14 can also function as a wafer pre-alignment station. At the wafer pre-alignment station, a notch (not shown) in the wafer 18 is located and the position of the wafer 18 is precisely determined so that the usable features can be transferred to the proper location on the substrate usable region 220.

The transfer mechanism 16 transfers the substrate 18 between the exposure apparatuses 12, 14 and loads the substrate 18 on the respective wafer stage 50, 81. The transfer mechanism 16 can include one or more robotic arms.

FIG. 2 is a simplified top view of one non-exclusive embodiment of the wafer 18 that has been processed with the exposure assembly 10 of FIG. 1. In this embodiment, the wafer 18 is a generally disk shaped, thin slice of semiconductor material that serves as a substrate for photolithographic patterning. Typically, the disk shaped wafer 18 is divided into a plurality of rectangular shaped integrated circuits 283. In this embodiment, the integrated circuits 283 define the substrate usable region 220, and the rest of the wafer defines the substrate edge region 222.

Stated in another fashion, the substrate usable region 220 is defined by the area of the wafer 18 that will become usable integrated circuits 283, and the substrate edge region 222 is defined by the area of the wafer 18 that will not become usable integrated circuits 83. As provided above, the primary exposure apparatus 12 (illustrated in FIG. 1) is used for transferring usable features “uf” to only a substrate usable region 220, and the ES exposure apparatus 14 is used for rapidly transferring edge features “ef” to only the substrate edge region 222.

It should be noted that depending upon the desired wafer design, the edge features can be controlled to have similar characteristics to the usable features or the edge features can be controlled to be quite different to the usable features.

FIG. 3A is a simplified top illustration of a first embodiment of an ES reticle 357A having features of the present invention. In this embodiment, the ES reticle 357A includes a plurality of alternative reticle patterns 384A that are aligned in a one dimensional array. In FIG. 3A, the ES reticle 357A includes five different reticle patterns 384A, labeled A, B, C, D, and E. Alternatively, the ES reticle 357A can be designed to have greater than five or fewer than five different reticle patterns 384A.

As provided herein, each of the reticle patterns 384A can have a different transmissibility, and/or different reticle features 385 (represented as a line). For example, the different reticle patterns 384A can have different reticle characteristics such as different line spacings, different line widths, different line shapes, and/or different line lengths. As non-exclusive examples, the reticle patterns 384A can have a transmissibility of approximately 10, 20, 30, 40, 50, 60, 70, 80, 90, or 100 percent, and the reticle patterns 384A can have a line width of approximately ½, 1, 2, 3, 4, or 5 microns. For example, (i) the A reticle pattern 384A can have a transmissibility of approximately 50 percent and a line width of ½ micron; (ii) the B reticle pattern 384A can have a transmissibility of approximately 90 percent and a line width of 1 micron; (iii) the C reticle pattern 384A can have a transmissibility of approximately 70 percent and a line width of 2 microns; (iv) the D reticle pattern 384A can have a transmissibility of approximately 40 percent and a line width of 4 microns; and (v) the E reticle pattern 384A can have a transmissibility of approximately 30 percent and a line width of 5 microns. The reticle features 385 in the reticle patterns 384A can be different or similar to the patterns transferred to wafer 18 by the primary exposure apparatus 12. It should be noted that the line shape and orientation are different in the reticle patterns illustrated in FIG. 3A. Moreover, other line shapes, positions and spacing are also possible.

It should be noted that the multiple alternative reticle patterns 384A in the ES reticle 357A provides good flexibility in controlling the characteristics (e.g. size and/or shape) of the features that are transferred to the substrate edge region 222.

With the present design, the ES reticle stage mover 78 (illustrated in FIG. 1) can move the ES reticle 357A along the X axis to adjust which of the patterns 384A is in the path of the illumination beam 72 (illustrated in FIG. 1), and to adjust the characteristics of the image beam 76 (illustrated in FIG. 1) that is directed onto the wafer 18 (illustrated in FIG. 1).

With the present invention, the goal is to print features and not just expose the substrate edge region 222.

In FIG. 3A, each of the patterns 384A is shaped somewhat similar to a wide, wedge shaped radial line. Alternatively, one or more of the reticle patterns 384A can have a different configuration than that illustrated in FIG. 3A.

FIG. 3B is a simplified top illustration of a second embodiment of an ES reticle 357B. In this embodiment, the ES reticle 357B includes a plurality of alternative reticle patterns 384B that are aligned in a two dimensional array. In FIG. 3B, the ES reticle 357B includes fifty different patterns 384B. Alternatively, the ES reticle 357B can be designed to have greater than fifty or fewer than fifty different patterns 384B. The multiple alternative reticle patterns 384B provide good flexibility in controlling the characteristics of the features that are transferred to the substrate edge region 222.

As provided herein, each of the reticle patterns 384B can have different reticle characteristics such as a different transmissibility, a different line spacing, a different line shape, a different line length, and/or a different line width. As non-exclusive examples, the reticle patterns 384B can have a transmissibility of approximately 10, 20, 30, 40, 50, 60, 70, 80, 90, or 100 percent, and the patterns 384A can have a line width of approximately ½, 1, 2, 3, 4, or 5 microns.

With this design, the reticle stage mover 78 (illustrated in FIG. 1) can move the ES reticle 357B along the X axis and along the Y axis to adjust which of the reticle patterns 384B is in the path of the illumination beam 72 (illustrated in FIG. 1), and to adjust the characteristics of the edge shot 76 (illustrated in FIG. 1) that is directed onto the wafer 18 (illustrated in FIG. 1).

Thus, this design allows for the degree of exposure to be precisely controlled in a manner to allow (i) the density (defined as the ratio of exposed vs. unexposed areas), (ii) the line spacing, and/or (iii) other feature characteristics to be selectively changed. Stated in another fashion, the ES reticle can be adjusted to adjust the density of the exposed regions and to define the small features that are transferred to the substrate edge region 222. With this design, the edge features transferred to the substrate edge region 222 can be controlled to mimic the usable features transferred to the substrate usable region 220.

FIG. 3C is a simplified top illustration of a third embodiment of an ES reticle 357C. In this embodiment, the ES reticle 357C again includes a plurality of alternative reticle patterns 384C that are aligned around the circumference of the disk shaped reticle. In FIG. 3C, the ES reticle 357C includes eight different reticle patterns 384C that each has different reticle characteristics. Alternatively, the ES reticle 357C can be designed to have greater than eight or fewer than eight different reticle patterns 384C.

As provided herein, each of the reticle patterns 384C can have a different transmissibility and/or a different line width. As non-exclusive examples, the reticle patterns 384C can have a transmissibility of approximately 10, 20, 30, 40, 50, 60, 70, 80, 90, or 100 percent, and the reticle patterns 384A can have a line width of approximately ½, 1, 2, 3, 4, or 5 microns.

With this design, the reticle stage mover 78 (illustrated in FIG. 1) can rotate the ES reticle 357C about the Z axis to adjust which of the reticle patterns 384C is in the path of the illumination beam 72 (illustrated in FIG. 1), and to adjust the characteristics of the image beam 76 (illustrated in FIG. 1) that is directed onto the wafer 18 (illustrated in FIG. 1).

Moreover, the reticle stage mover 78 can move the ES reticle 357C relative to the illumination beam to effectively vary the feature characteristics (e.g. the line widths, line sizes, line spacing or other characteristics) of the edge features in a quazi-continuous manner. Further, for example, if one of the reticle patterns 384B is only partly in the illumination beam, it will transfer different edge features than if the reticle pattern is fully in the illumination beam. Further, a width of the edge feature being transferred can be adjusted by adjusting the position of the reticle pattern 384B relative to the illumination beam.

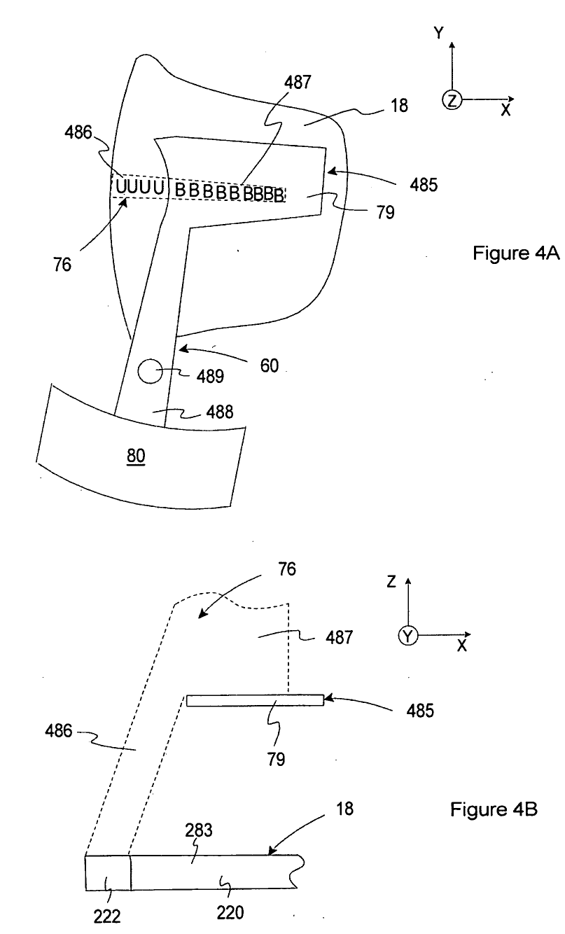

FIG. 4A is a simplified top view of a portion of the image beam 76 (illustrate in phantom) from the ES reticle 57 (not shown in FIG. 4A), the shutter assembly 60 in a first shutter position 485, and a portion of the substrate 18.

In this embodiment, the image beam 76 is shaped somewhat similar to a wide, wedge shaped radial line. Further, the image beam 76 includes (i) an unblocked beam portion 486 (highlighted with “U's”) that is directed at the substrate edge region 222 (illustrated in FIG. 4B), and (ii) a blocked beam portion 487 (highlighted with “B's”) that is blocked by the shutter 79 and is not projected onto the wafer 18. As a result thereof, the shutter 79 inhibits the beam portion 487 from being projected onto the substrate usable region 220 (illustrated in FIG. 4B). In this embodiment, the shutter assembly 60 includes the shutter 79, the shutter mover 80, a shutter arm 488 (e.g. a rigid beam), and a shutter axis 489 (e.g. a bearing). In this embodiment, the shutter 79 is a piece of material that inhibits the transmission of light at the wavelength of the image beam 76. For example, the shutter 79 can be made to be light weight (e.g. one or two grams) to facilitate rapid movement of the shutter 79.

In FIG. 4A, the shutter 79 is illustrated in the first shutter position 485. However, the shutter 79 can be precisely moved to a number of different positions to adjust the shape of the unblocked beam portion 486 and blocked beam portion 487.

The shutter mover 80 rapidly moves the shutter 79 relative to the image beam 76 to quickly adjust the amount of the image beam 76 that is blocked or not blocked by the shutter 79 and to ultimately adjust the shape of the unblocked beam portion 487 that is directed onto the wafer 18. In one non-exclusive embodiment, the shutter mover 80 is a voice coil motor that pivots the shutter 79 and the shutter arm 488 about the shutter pivot 489 (about the Z axis). Alternatively, the shutter mover 80 can be another type of actuator.

FIG. 4B is a simplified side view of the image beam 76 (illustrated in phantom) including the unblocked beam portion 486 and the blocked beam portion 487, the shutter 79, and a portion of the substrate 18 with the shutter 79 in the first shutter position 485. In FIG. 4B, the integrated circuit 283, the substrate usable region 220, and the substrate edge region 222 are also illustrated.

In the first shutter position 485, the shutter 79 inhibits the image beam 76 from being directed onto the integrated circuit 283 and the substrate usable region 220. Stated in another fashion, the shutter 79 is precisely moved to adjust the radial length of the image beam 76 so that the unblocked beam portion 486 traces the edge of the outer integrated circuits 283 as wafer 18 rotates.

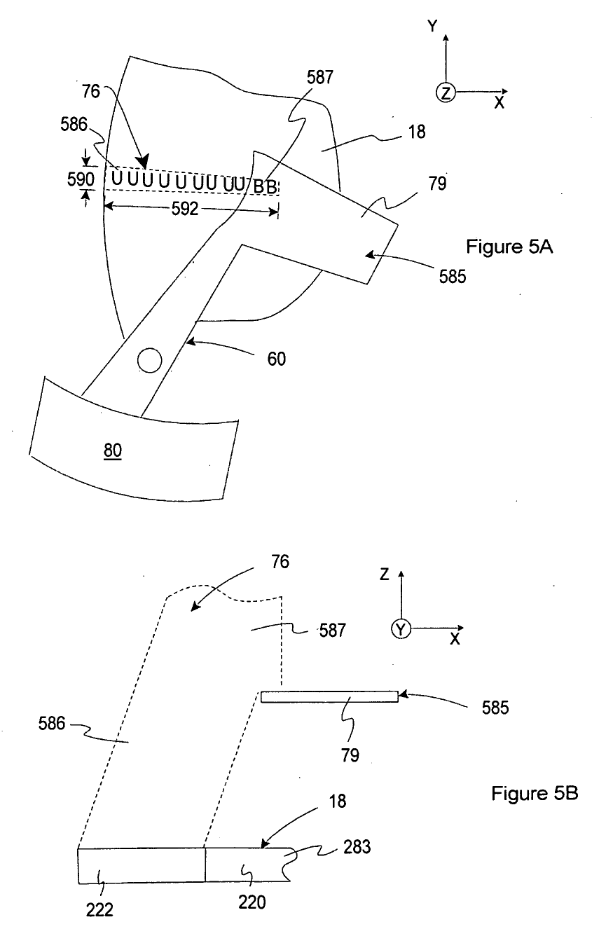

FIG. 5A is a simplified top view of a portion of the image beam 76 (illustrate in phantom) from the ES reticle 57 (not shown in FIG. 5A), the shutter assembly 60 in a second shutter position 585, and a portion of the substrate 18.

In this embodiment, the image beam 76 is again shaped somewhat similar to a wide, wedge shaped radial line. Further, the image beam 76 includes (i) an unblocked beam portion 586 (highlighted with “U's”) that is directed at the substrate edge region 222 (illustrated in FIG. 5B), and (ii) a blocked beam portion 587 (highlighted with “B's”) that is blocked by the shutter 79 and is not projected onto the wafer 18. As a result thereof, the shutter 79 inhibits the blocked beam portion 587 from being projected onto the substrate usable region 220 (illustrated in FIG. 5B).

In FIG. 5A, the shutter 79 is illustrated in the second shutter position 585. However, the shutter 79 can be precisely moved to a number of different positions to adjust the shape of the unblocked beam portion 586 and blocked beam portion 587.

The shutter mover 80 rapidly moves the shutter 79 relative to the image beam 76 to quickly adjust the amount of the image beam 76 that is blocked or not blocked by the shutter 79 and to ultimately adjust the shape of the unblocked beam portion 587 that is directed onto the wafer 18.

FIG. 5B is a simplified side view of the image beam 76 (illustrated in phantom) including the unblocked beam portion 586 and the blocked beam portion 587, the shutter 79, and a portion of the substrate 18 with the shutter 79 in the second shutter position 585. In FIG. 5B, the integrated circuit 283, the substrate usable region 220, and the substrate edge region 222 are also illustrated.

In the second shutter position 585, the shutter 79 inhibits the image beam 76 from being directed onto the integrated circuit 283 and the substrate usable region 220. Stated in another fashion, the shutter 79 is precisely moved to adjust the radial length of the image beam 76 so that the unblocked beam portion 586 traces the edge of outer integrated circuits 283 as wafer 18 rotates.

Referring back to FIG. 5A, the image beam 76 at the wafer can have a beam width 590 and a beam length 592. In one non-exclusive embodiment, the beam width 590 is approximately 94 micrometers, and the beam length 592 is approximately 25 millimeters. However, the system could be design so that the image beam 76 has a different shape and/or dimensions than those described herein.

It should be noted that in this embodiment, the movement of the shutter 79 causes the length of the unblocked beam portion 586 to change without changing the width of the unblocked beam portion 586. In one embodiment, the shutter 79 can be moved so that the unblocked beam portion 586 has a length of approximately zero, a length that is equal to the beam length 592 (25 millimeters in the example above) or any length therebetween.

It should also be noted that the width of the unblocked beam portion 586 can be changed by moving the ES reticle 57 (not shown in FIG. 5A). More specifically, the width can be adjusted by adjusting the alignment of a particular pattern to the illumination beam. For example, the width can be adjusted by moving a portion of the pattern out of the path of the illumination beam.

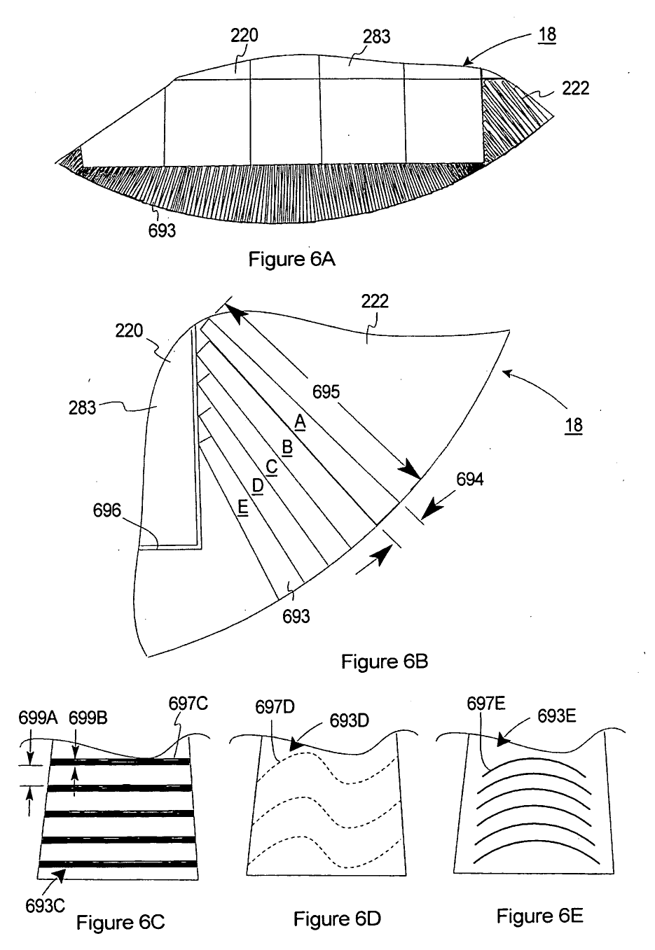

FIG. 6A is a simplified top view of one non-exclusive embodiment of a portion of a wafer 18 with a plurality of adjacent edge shots 693 that were transferred to a number of alternative locations in the substrate edge region 222. It should be noted that the edge shots 693 were not transferred to the substrate usable region 220 and that the length of each of the transferred edge shots 693 is adjusted so that the edge shots 693 trace the outer boundary of the integrated circuits 238.

In FIG. 6A, the plurality of edge shots 693 are substantially side by side without substantial gaps. Alternatively, the edge shots 693 could be transferred with gaps between edge shots 693.

FIG. 6B illustrates a relatively small part of a wafer 18 with only five, radial segment shaped edge shots 693 (labeled A-E) transferred to the substrate edge region 222. In this embodiment, each of the edge shots 693 includes a shot width 694 and a shot length 695. FIG. 6B more clearly illustrates that the shot length 695 of each edge shots 693 can be adjusted so that the edge shots 693 trace the outer boundary of the integrated circuits 238. As a reminder, in one embodiment, the shot length 695 is quickly and precisely adjusted by moving the shutter 79 (illustrated in FIG. 1) to quickly adjust the inner radial part of the edge shots 693. With this design, the system exposes relatively small radial segments of the wafer edge.

Further, the shutter (not shown in FIG. 6B) can be moved to limit the exposure of the inner radial part of the beam so that integrated circuits 238 are not exposed at this time. The radial segments can be transferred in a step wise fashion or a continuous fashion.

FIG. 6B also illustrates that the integrated circuit 283 includes a scribe line 696, and that the edge shots 693 are not transferred into the scribe line 696, the integrated circuits 283, and the substrate usable region 220.

In one, non-exclusive embodiment, each edge shot 693 has a maximum shot length 695 of approximately 25 millimeters, and a shot width 694 of approximately 94 micrometers.

It should be noted that the edge shots 693 can be transferred to the edge of the wafer in a sequentially fashion, or the edge features 693 can be transferred to the wafer in a non-sequential fashion during multiple rotations of the wafer.

FIGS. 6C-6E illustrate portions of alternative, non-exclusive edge shots 693C, 693D, 693E transferred to a wafer. In these Figures, each edge shot 693C, 693D, 693E includes a plurality of edge features 697C, 697D, 697E that were transferred to the wafer. It should be noted that the characteristics (e.g. line spacing 699A, line widths 699B, shape, length, pattern, and/or densities) of the edge features 697C, 697D, 697E can be varied pursuant to the teachings provided herein to achieve the desired characteristics on the wafer edge.

It should be noted that the edge shots 693C, 693D, 693E illustrated in FIGS. 6C-6E has a different features pattern. For example, (i) in FIG. 6C, each of the edge features 697C is a straight solid line that extends transversely across the edge shot 693C, (ii) in FIG. 6D, each of the edge features 697D is a curved, dashed line that extends transversely across the edge shot 693E, and (iii) in FIG. 6E, each of the edge features 697E is an arched, solid line that extends transversely across a portion of the edge shot 693E. It should that line spacings, the line shape, and the line type are different when comparing the edge shot 693C in FIG. 6C to the edge shot 693D in FIG. 6D. Further, the line width, the line spacing, the line shape, the line length are different when comparing the edge shot 693C in FIG. 6C to the edge shot 693E in FIG. 6E.

Alternatively, one or more of the edge features 697C, 697D, 697E can have a line or a line segment having a shape, thickness, orientation, and/or spacing that is different than that illustrated in FIGS. 6C, 6D, 6E. For example, one or more of the edge features 697C, 697D, 697E can be wedged shaped, or orientated lengthwise along the respective edge shot 693C, 693D, 693E. Further, the lines in each edge shot 693C, 693D, 693E can be continuous or discontinuous.

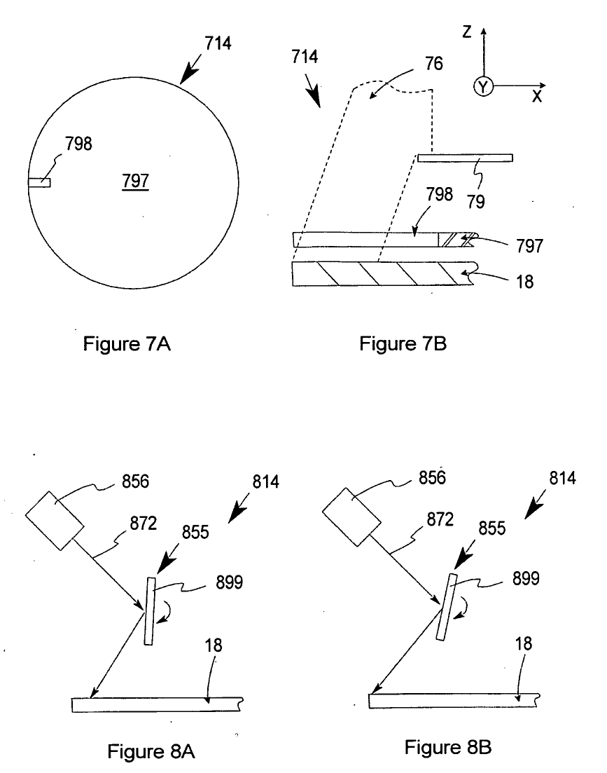

FIG. 7A is a simplified top illustration and FIG. 7B is a simplified cut-away illustration of a portion of another embodiment of an ES exposure apparatus 714 having features of the present invention. In this embodiment, the ES exposure apparatus 714 includes a mask 797 that is positioned near the wafer 18 (possible between the wafer 18 and the ES optical assembly 61 (illustrated in FIG. 1)). The mask 797 inhibits unwanted stray light from the image beam 76 from being directed onto the wafer 18. In this embodiment, the mask 797 is generally disk shaped and has a diameter that is similar to that of the wafer 18. Further, in this embodiment, the proximity mask 797 includes a mask aperture 798 that allows the image beam 76 to be directed onto the substrate 18. It should be noted that the shutter 79 is also illustrated in FIG. 7B.

Further, it should be noted that in certain embodiments, that the mask 797 is stationary with the mask aperture 798 aligned with the image beam 76, and that the wafer 18 is rotated relative to the mask 797 and the image beam 76.

FIGS. 8A and 8B are a simplified illustration of a portion of yet another embodiment of an ES exposure apparatus 814 having features of the present invention. In this embodiment, the feature transferer 855 is different than the embodiments described above. More specifically, in this embodiment, the feature transferer 855 includes an ES illumination system 856 that generates an illumination beam 872 (e.g. a point beam) that is directed at a beam redirector 899. Subsequently, the beam redirector 899 is moved (e.g. rotated (compare FIGS. 8A and 8B)) to cause the illumination beam 872 to be moved across the wafer 18 and one edge feature (not shown in FIGS. 8A and 8B) to be transferred to the wafer 18. With this design, the beam redirector 899 can be moved back and forth to transfer the edge features (e.g. lines and line segments) to the wafer 18.

For example, the beam redirector 899 can be a mirror, a diffraction grating, a prism, or another reflective device.

It should be noted that the mask 797 illustrated in FIG. 7 can be used in the embodiment illustrated in FIGS. 8A and 8B or any of the other embodiments disclosed herein.

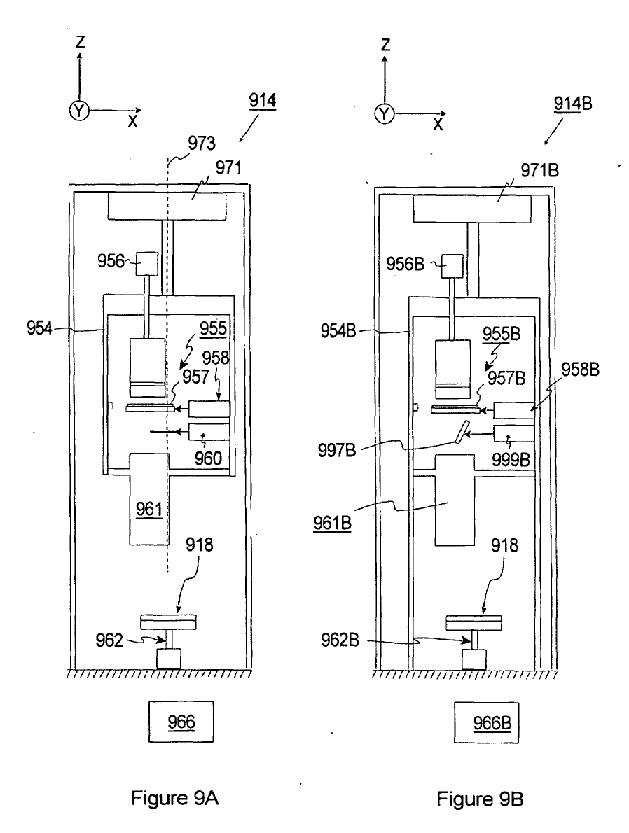

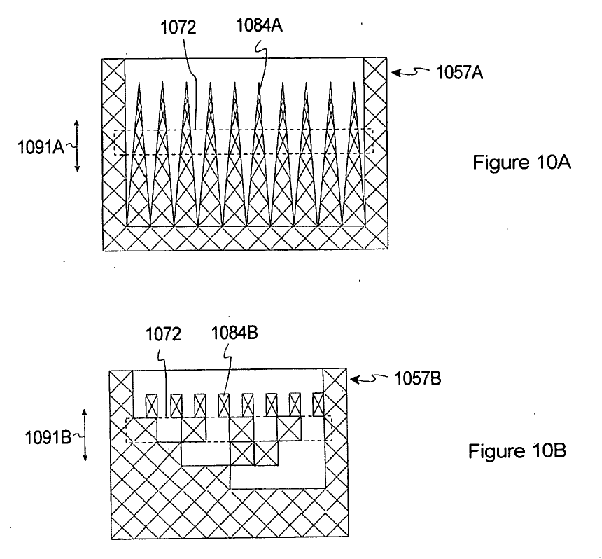

FIG. 9A is a simplified illustration of another embodiment of an ES exposure apparatus 914 that is somewhat similar to the corresponding ES exposure apparatus 14 described above and illustrated in FIG. 1. In FIG. 9A, the ES exposure apparatus 914 again includes (i) an ES apparatus frame 954, (ii) a feature transferer 955 that includes an ES illumination system 956 (irradiation apparatus), an ES reticle 957, an ES reticle stage assembly 958, and a shutter assembly 960, (iii) an ES optical assembly 961, (iv) an ES wafer stage assembly 962, and (v) an ES control system 966.

However, in this embodiment, the ES exposure apparatus 914 includes a stage assembly 971 for rotating the feature transferer 955, the ES optical assembly 961 and a portion of the ES apparatus frame 954 about an assembly axis 973. With this design, the stage assembly 971 can rotate these components instead of the ES wafer stage assembly 962 rotating the substrate 918 during the transfer of edge features. Alternatively, the stage assembly 971 can rotate these components in conjunction with the ES wafer stage assembly 962 rotating the substrate 918.

It should be noted the ES wafer stage assembly 962 can include one or more movers (not shown) to move the substrate along the X axis or along the Y axis. With this design, the ES control system 966 can control both the position of the shutter assembly 960 and the position of the substrate 918 (via the ES wafer stage assembly 962) based on the shape of the substrate edge region (not shown in FIG. 9A) to contour the image beam (not shown in FIG. 9A) along edge of the substrate usable region (not shown in FIG. 9A).

FIG. 9B is a simplified illustration of another embodiment of an ES exposure apparatus 914B that is somewhat similar to the corresponding ES exposure apparatus 14 described above and illustrated in FIG. 1. In FIG. 9B, the ES exposure apparatus 914B again includes (i) an ES apparatus frame 954B, (ii) a feature transferer 955B that includes an ES illumination system 956B (irradiation apparatus), an ES reticle 957B, and an ES reticle stage assembly 958B, (iii) an ES optical assembly 961B, (iv) an ES wafer stage assembly 962B that rotates the wafer 918, and (v) an ES control system 966B.

However, in this embodiment, instead of a movable shutter, the feature transferer 955B includes a edge shot redirector 997B that is selectively moved (e.g. rotated) by a redirector mover 999B that is controlled by the ES control system 966B. This causes the image beam (not shown in FIG. 9B) to be selectively moved and the resulting edge shots (not shown in FIG. 9B) to trace and the outer boundary of the integrated circuits (not shown in FIG. 9B). For example, the edge shot redirector 997B can be a mirror, a diffraction grating, a prism, or another reflective device.

FIG. 10A illustrates another embodiment of an ES reticle 1057A having features of the present invention. In this embodiment, the ES reticle 1057A includes a single reticle pattern 1084A shaped somewhat like the teeth of a comb. However, other patterns can be used to achieve desired variety in features. In FIG. 10A, the “X's” denote that this area of the ES reticle 1057A is opaque, while the area without “X's” denote that this area of the ES reticle 1057A is clear. It should be noted that the clear and opaque areas can be switched. Additionally, rectangular dashed line 1072 represents the illumination beam that is directed onto the ES reticle 1057A by the ES illumination source (not shown in FIG. 10A).

In this embodiment, the ES reticle 1057A can be selectively moved (via the ES control system controlling the ES reticle stage assembly) along axis 1091A relative to the illumination beam 1072 to selectively adjust the portion of the pattern 1084A that is in the path of the illumination beam 1072, and ultimately selectively adjust and vary the features characteristics (e.g. line widths, line spacings, line sizes, line lengths, and/or density (defined by the ratio of the exposed vs. unexposed)) of the edge features transferred to the substrate edge region (not shown).

For example, by moving the ES reticle 1057A along axis 1091A, the widths of the exposed lines can be changed relative to the unexposed lines, thereby altering the line width to line space ratio, and thereby altering the density of the exposed area of the substrate edge region. With the design illustrated in FIG. 10A, the ES reticle 1057A can be moved to continuously adjust the ratio of exposed to unexposed from approximately zero percent to approximately one hundred percent (the limit depending upon the characteristics of the photoresist process).

FIG. 10B illustrates another embodiment of an ES reticle 1057B having features of the present invention. In this embodiment, the ES reticle 1057A includes another reticle pattern 1084B. In FIG. 10B, the “X's” again denote that this area of the ES reticle 1057A is opaque, while the area without “X's” denote that this area of the ES reticle 1057A is clear. It should be noted that the clear and opaque areas can be switched. Additionally, rectangular dashed line 1072 again represents the illumination beam that is directed onto the ES reticle 1057B by the ES illumination source (not shown in FIG. 10B).

In this embodiment, the ES reticle 1057B can be selectively moved (via the ES reticle stage assembly) along axis 1091B relative to the illumination beam 1072 to selectively adjust the portion of the reticle pattern 1084B that is in the path of the illumination beam 1072, and ultimately selectively adjust and vary the feature characteristics (e.g. line widths, line spacings, line sizes, and/or density (defined by the ratio of the exposed vs. unexposed)) of the edge features transferred to the substrate edge region (not shown).

For example, in this embodiment, by moving the ES reticle 1057B along axis 1091B in the center portion of the ES reticle 1057B, the line spacing, the line positions, and the line widths can be selectively changed without changing the density of the features being transferred to the wafer. Thus a different feature pattern can be transferred to the wafer without changing the density of the features.

It should be noted that a single ES reticle can have both the patterns 1084A, 1084B illustrated in FIGS. 10A and 10B, or combinations of the patterns 1084A, 1084B, in addition to other patterns.

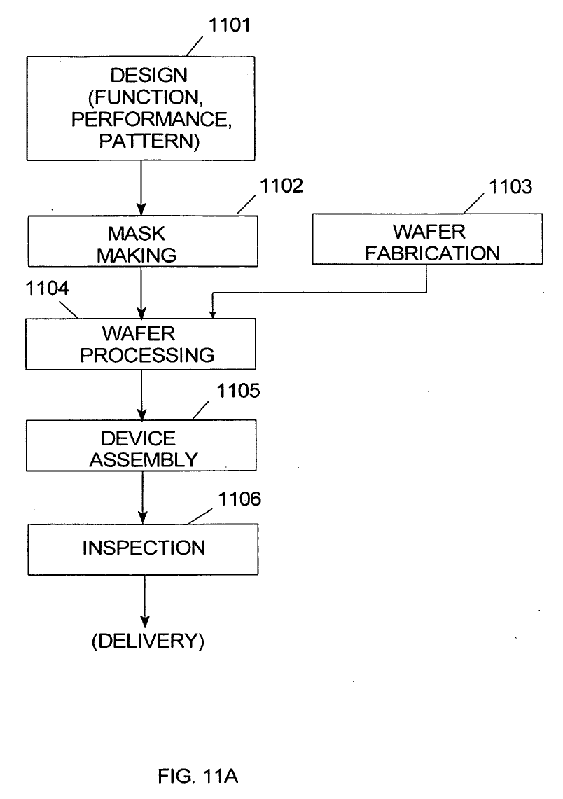

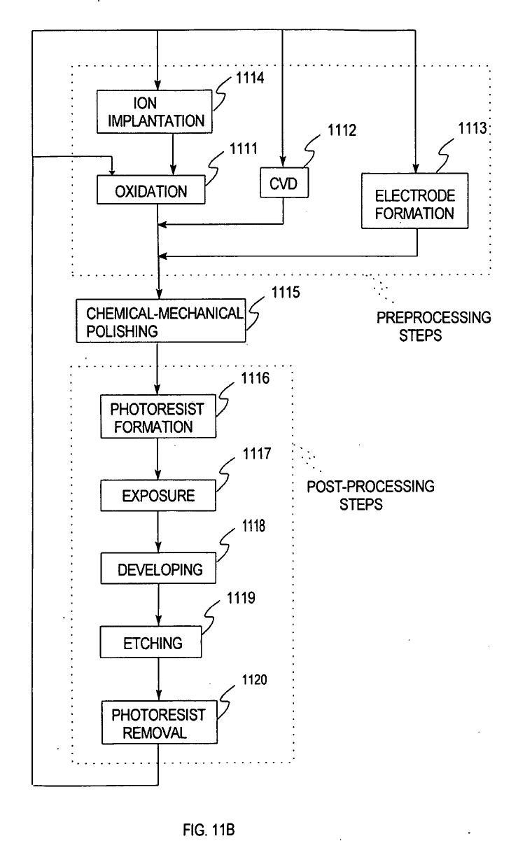

Semiconductor devices can be fabricated using the above described systems, by the process shown generally in FIG. 11A. In step 1101 the device's function and performance characteristics are designed. Next, in step 1102, a mask (reticle) having a pattern is designed according to the previous designing step, and in a parallel step 1103 a wafer is made from a silicon material. The mask pattern designed in step 1102 is exposed onto the wafer from step 903 in step 1104 by a photolithography system described hereinabove in accordance with the present invention. In step 1105, the semiconductor device is assembled (including the dicing process, bonding process and packaging process), finally, the device is then inspected in step 1106.

FIG. 11B illustrates a detailed flowchart example of the above-mentioned step 1104 in the case of fabricating semiconductor devices. In FIG. 11B, in step 1111 (oxidation step), the wafer surface is oxidized. In step 1112 (CVD step), an insulation film is formed on the wafer surface. In step 1113 (electrode formation step), electrodes are formed on the wafer by vapor deposition. In step 1114 (ion implantation step), ions are implanted in the wafer. The above mentioned steps 1111-1114 form the preprocessing steps for wafers during wafer processing, and selection is made at each step according to processing requirements.

At each stage of wafer processing, when the above-mentioned preprocessing steps have been completed, optionally in step 1115 the wafer can be polished using Chemical-Mechanical Polishing (“CMP”). Typically, CMP is done with certain layers depending upon the processing steps as required by the integrated circuit manufacturing process.

Subsequently, the following post-processing steps are implemented. During post-processing, primary, in step 1116 (photoresist formation step), photoresist is applied to a wafer. Next, in step 1117 (exposure step), the above-mentioned exposure device is used to transfer the circuit pattern of a mask (reticle) to a wafer. Then in step 1118 (developing step), the exposed wafer is developed, and in step 1119 (etching step), parts other than residual photoresist (exposed material surface) are removed by etching. In step 1120 (photoresist removal step), unnecessary photoresist remaining after etching is removed. Multiple circuit patterns are formed by repetition of these preprocessing and post-processing steps.

The exposure apparatuses described herein can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

While the particular exposure apparatuses as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. An ES exposure apparatus for transferring edge features to a substrate edge region of a substrate, the ES exposure apparatus comprising:
a feature transferer that transfers one or more edge features to the substrate edge region; and
a stage assembly that rotates at least one of the substrate and the feature transferer to allow the feature transferer to transfer the edge features to a plurality of locations around the substrate edge region.

2. The ES exposure apparatus of claim 1 wherein the feature transferer exposes a radial segment of the substrate edge region; wherein the feature transferer includes a shutter that is movable to limit a length of the radial segment being exposed on the substrate; and wherein the feature transferer includes an ES illumination system that generates an illumination beam that is appropriate for a sensitivity of a photo resist on the substrate.

3. The ES exposure apparatus of claim 2 wherein the feature transferer is selectively controlled to control a density of the edge features being transferred to the substrate edge region.

4. The ES exposure apparatus of claim 2 wherein the feature transferer is selectively controlled to adjust a features pattern of the edge features transferred to the substrate edge region.

5. The ES exposure apparatus of claim 2 wherein the feature transferer includes an ES reticle having a reticle pattern with one or more reticle features that are imaged onto the substrate.

6. The ES exposure apparatus of claim 5 wherein the ES reticle includes a plurality of alternative reticle patterns and wherein the feature transferer includes an ES reticle stage assembly that moves the desired reticle pattern into a path of the illumination beam.

7. The ES exposure apparatus of claim 5 wherein the feature transferer includes an ES reticle stage assembly that moves the reticle pattern to vary the characteristics of the edge features that are transferred to the substrate edge region.

8. The ES exposure apparatus of claim 1 wherein the feature transferer includes an ES reticle having a reticle pattern with one or more reticle features, and an ES illumination system that directs an illumination beam at the ES reticle to create an image beam that is directed at the substrate.

9. The ES exposure apparatus of claim 8 wherein the feature transferer includes a shutter that is movable relative to the reticle to adjust a shape of the image beam that is directed at the substrate.

10. The ES exposure apparatus of claim 8 wherein the ES reticle includes a plurality of alternative reticle patterns and wherein the feature transferer includes an ES reticle stage assembly that moves the desired reticle pattern into a path of the illumination beam.

11. The ES exposure apparatus of claim 8 wherein the feature transferer includes an ES reticle stage assembly that moves the ES reticle to adjust the characteristics of the one or more edge features that are transferred to the substrate edge region.

12. The ES exposure apparatus of claim 8 wherein the ES illumination system includes a pulsing laser.

13. The ES exposure apparatus of claim 8 wherein the ES illumination system includes a continuous laser.

14. The ES exposure apparatus of claim 1 further comprising a mask positioned adjacent the substrate that inhibits stray light from the feature transferer from being directed at a substrate usable region of the substrate.

15. The ES exposure apparatus of claim 1 further comprising a shutter and a control system that controls the position of at least one the shutter and the substrate based on a shape of the substrate edge region.

16. The ES exposure apparatus of claim 1 wherein the stage assembly rotates the substrate at least approximately 360 degrees about a substrate axis of the substrate.

17. The ES exposure apparatus of claim 1 wherein the feature transferer includes an illumination system that generates an illumination beam, and a beam redirector that moves the illumination beam relative to the wafer to transfer the edge features to the wafer.

18. An exposure assembly comprising a primary exposure apparatus that transfers features to a substrate usable region of the substrate, and the ES exposure apparatus of claim 1 that transfers features to the substrate edge region.

19. A process for manufacturing a wafer that includes the steps of providing a substrate, and transferring features to the substrate with the exposure assembly of claim 18.

20. An exposure assembly for transferring features to a substrate that includes a substrate edge region, a substrate usable region, and a substrate axis, the exposure assembly comprising:
a primary exposure apparatus that transfers one or more usable features to the substrate usable region; and
an ES exposure apparatus that transfers one or more edge features to the substrate edge region, the ES exposure apparatus comprising (i) an ES reticle having a pattern with one or more features, (ii) an ES illumination system that directs an illumination beam at the ES reticle to create an image beam that is directed at the substrate; and (iii) an ES wafer stage assembly that rotates the substrate about the substrate axis to allow the image beam to transfer the edge features to a plurality of alternative locations of the substrate edge region.

21. The exposure assembly of claim 20 wherein the ES exposure apparatus includes a shutter that is movable relative to the reticle to adjust the shape of the image beam that is directed at the substrate.

22. The exposure assembly of claim 20 wherein the image beam is radial segment shaped; wherein the shutter is movable to limit a length of the radial segment being exposed on the substrate; and wherein the ES reticle is movable to adjust the characteristics of the edge features being transferred to the substrate edge region.

23. The exposure assembly of claim 20 wherein the ES reticle includes a plurality of alternative reticle patterns, and wherein the ES exposure apparatus includes an ES reticle stage assembly that moves the desired reticle pattern into a path of the illumination beam.

24. The exposure assembly of claim 20 further comprising a shutter and a control system that controls the position of at least one the shutter and the substrate based on a shape of the substrate edge region.

25. The exposure assembly of claim 20 wherein the primary exposure apparatus is a step and repeat type exposure apparatus.

26. The exposure assembly of claim 20 wherein the primary exposure apparatus is a scanning type exposure apparatus.

27. A process for manufacturing a wafer that includes the steps of providing a substrate, and forming features on the substrate with the exposure assembly of claim 20.

28. An ES exposure apparatus for transferring edge features to a substrate edge region of a substrate that includes a substrate axis, the ES exposure apparatus comprising:
an ES reticle having a pattern with one or more reticle features to be transferred to the substrate edge region;
a wafer stage configured to hold the substrate;
a feature transferer that generates an image beam, the feature transferer including a shutter that is configured to adjust a shape of the image beam that is directed at the substrate; and
a control system configured to control at least one of the position of the shutter and the wafer stage based on a shape of the substrate edge region.

29. The ES exposure apparatus of claim 28 wherein the feature transferer exposes a radial segment of the substrate edge region; wherein the shutter that is movable to limit a length of the radial segment being exposed on the substrate; wherein the feature transferer is selectively controlled to control the characteristics of the edge features being transferred to the substrate edge region; and wherein the feature transferer includes an ES illumination system that generates an illumination beam that is appropriate for a sensitivity of a photo resist on the substrate.

30. A method for transferring features to a substrate, the method comprising the steps of:
transferring usable features to a substrate usable region of the substrate with a primary exposure apparatus; and
transferring edge features to a substrate edge region of the substrate with an ES exposure apparatus.

31. The method of claim 30 wherein the step of transferring edge features includes the steps of (i) transferring one or more edge features to the substrate edge region with the feature transferee, and (ii) rotating the substrate about a substrate axis with an ES wafer stage assembly to allow the ES feature transferer to transfer the edge features to a plurality of alternative locations in the substrate edge region.

32. The method of claim 31 wherein the feature transferer includes an ES reticle having a reticle pattern with one or more reticle features, and an ES illumination system that directs an illumination beam at the ES reticle to create an image beam that is directed at the substrate.

33. The method of claim 32 wherein the feature transferer includes a shutter that is movable relative to the reticle to adjust the shape of the image beam that is directed at the substrate.

34. The method of claim 32 wherein the ES reticle includes a plurality of alternative reticle patterns and wherein the feature transferer includes an ES reticle stage assembly that moves the desired reticle pattern into the path of the illumination beam.

35. The method of claim 30 wherein the step of transferring edge features includes the steps of (i) exposing a radial segment of the substrate edge region; (ii) adjusting a length of the radial segment with a movable shutter; and (iii) generating an illumination beam that is appropriate for a sensitivity of a photo resist on the substrate.

36. The method of claim 35 wherein the step of transferring edge features includes the step of adjusting the characteristics of the edge features transferred with a reticle.
